(19) United States
(12) Patent Application Publication
(10) Pub. No.: US 2006/0278923 A1
(43) Pub. Date: Dec. 14, 2006

(54) Integrated circuit and method for manufacturing an integrated circuit

(76) Inventors: Volker Dudek, Brackenheim (DE); Michael Graf, Leutenbach (DE); Andre Heid, Marbach (DE); Stefan Schwantes, Heilbronn (DE)

Correspondence Address: MCGRATH, GEISSLER, OLDS & RICHARDSON, PLLC, P.O. BOX 1364, FAIRFAX, VA, 22038-1364, US

(21) Appl. No.: 11/452,300

(22) Filed: Jun. 14, 2006

(30) Foreign Application Priority Data
Jun. 14, 2005 (DE) DE10 2005 027 369

(51) Int. Cl. H01L 29/76

(52) U.S. Cl. 257/335

(57) ABSTRACT

An integrated circuit is disclosed that includes a component region with at least one NDMOS transistor and at least one PDMOS transistor and a substrate, which is isolated from the component region by a dielectric, whereby the component region, dielectric, and substrate form a first substrate capacitance standardized to a unit area in a first region of the PDMOS transistor and a second substrate capacitance standardized to said unit area in a second region of the NDMOS transistor, and whereby the first substrate capacitance standardized to said unit area is reduced in comparison to the second substrate capacitance standardized to said unit area.

This nonprovisional application claims priority under 35 U.S.C. §119(a) on German Patent Application No. DE 102005027369, which was filed in Germany on Jun. 14, 2005, and which is herein incorporated by reference.

### BACKGROUND OF THE INVENTION

1. Field of the Invention

The present invention relates to an integrated circuit and to a method for manufacturing an integrated circuit.

2. Description of the Background Art

DMOS transistors with high blocking voltages of, for example, 80 V and low on-resistances of a few milliohms are used in smart power circuits. In addition, analog and/or digital circuits for signal evaluation and control are provided in smart power circuits. Of DMOS transistors, both the N type (NDMOS transistor) and the P type (PDMOS transistor) are used.

### SUMMARY OF THE INVENTION

It is an object of the present invention to provide an integrated circuit with an NDMOS transistor and a PDMOS transistor. A second object of the present invention is to develop further a method for manufacturing an integrated circuit with an NDMOS transistor and a PDMOS transistor.

The integrated circuit has a component region with at least one NDMOS transistor and at least one PDMOS transistor. The component region therefore has semiconductor regions, for example, of silicon, which are formed by structuring and doping preferably as a source semiconductor region, drain semiconductor region, and body semiconductor region, and/or as a drift zone. DMOS transistors are field-effect transistors, which, for example, are formed for switching or controlling load currents for operating voltages of, for example, higher than 42 V. The PDMOS transistor thereby has a p-doped source semiconductor region and a p-doped drain semiconductor region, whereas the NDMOS transistor has an n-doped source semiconductor region and an n-doped drain semiconductor region.

Furthermore, the integrated circuit has a substrate, which is isolated from the component region by a dielectric. Substrates of this type isolated from the component region are also designated as SOI (semiconductor on insulator).

The component region, dielectric, and substrate form a first substrate capacitance standardized to a unit area in a first region of the PDMOS transistor and a second substrate capacitance standardized to the unit area in a second region of the NDMOS transistor. A unit area to which the substrate capacitance is standardized is, for example, 0.1 μm², 1 μm², or 10 μm². Due to this standardization, the substrate capacitances are therefore significantly dependent on the thickness of the dielectric and/or the permittivity (Pr).

The first substrate capacitance standardized to the unit area is reduced in comparison with the second substrate capacitance standardized to the unit area.

It is possible to reduce the first substrate capacitance in comparison with the second substrate capacitance by using a different dielectric material with a different permittivity, but it is provided in a first embodiment of the invention that the first substrate capacitance standardized to the unit area is reduced in comparison with the second substrate capacitance standardized to the unit area in that the dielectric in the first region of the PDMOS transistor has a greater first thickness in comparison with the second thickness of the dielectric in the second region of the NDMOS transistor.

In an embodiment, it is provided that the width of the first region is greater than the first thickness of the dielectric in said first region. Preferably, the width of the first region extends thereby across a transition region between the n-doped body and the p-doped drift zone of the PDMOS transistor.

According to another embodiment of the invention, the first substrate capacitance standardized to the unit area is reduced in comparison with the second substrate capacitance standardized to the unit area by removing locally the substrate in the first region of the PDMOS transistor. In said first region, therefore, the substrate is not present, whereas it remains in the second region of the NDMOS transistor and functions there advantageously as a substrate electrode.

In an advantageous embodiment of this variant of a further embodiment, the first region is a transition region of an N-well and a P-well of the PDMOS transistor. With an applied operating voltage, the P-well preferably defines a drift zone, whereas the N-well defines the body. The body can be connected to a desired potential, for example, via a highly n-doped semiconductor region.

According to another embodiment of the invention, a plurality of PDMOS transistors is formed in the first region and/or a plurality of NDMOS transistors in the second region. The PDMOS transistors are advantageously grouped close together locally in the first region by specific design rules. This also applies to the NDMOS transistors, which are advantageously grouped close together locally in the second region. Preferably, the first region is spatially distanced from the NDMOS transistors.

The method object is achieved by the following two embodiments of the invention.

In a first embodiment, a method for manufacturing an integrated circuit is provided, wherein a substrate, a dielectric adjacent to the substrate, and a semiconductor region adjacent to the dielectric are produced. For the manufacture, for example, two silicon wafers can be bonded one on top of another, at least one wafer having a silicon dioxide layer as the bonding area. The semiconductor region of the one wafer can be made thinner afterwards.

In the semiconductor region, at least one NDMOS transistor and one PDMOS transistor are formed. To form the transistors, the semiconductor region is structured and doped according to the type of the transistor.

To produce the dielectric, the dielectric is formed thicker in a first region of the PDMOS transistor than in a second region of the NDMOS transistor. In so doing, the dielectric is formed in time, preferably before the formation of transistor structures.

In a second embodiment, a method for manufacturing an integrated circuit is provided, wherein a dielectric adjacent to a substrate and a semiconductor region isolated from the substrate by the dielectric are produced.

In the semiconductor region, at least one NDMOS transistor and one PDMOS transistor are formed. To form the transistors, the semiconductor region is structured and doped according to the type of the transistor.

In a first region below the PDMOS transistor, the substrate is removed locally, particularly by etching. For local etching, the substrate is covered, for example, with an etching mask, which leaves exposed only the substrate within the first region for an etching attack. In this case, the etching can occur before or after the formation of the PDMOS transistor.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 a schematic plan view of an integrated circuit,

FIG. 2 a schematic sectional view of a first exemplary embodiment,

FIG. 3 a schematic sectional view of a second exemplary embodiment,

FIG. 4 a first schematic sectional view after a process step of a manufacture of an integrated circuit, and

FIG. 5 a second schematic sectional view after a process step of a manufacture of an integrated circuit.

### DETAILED DESCRIPTION

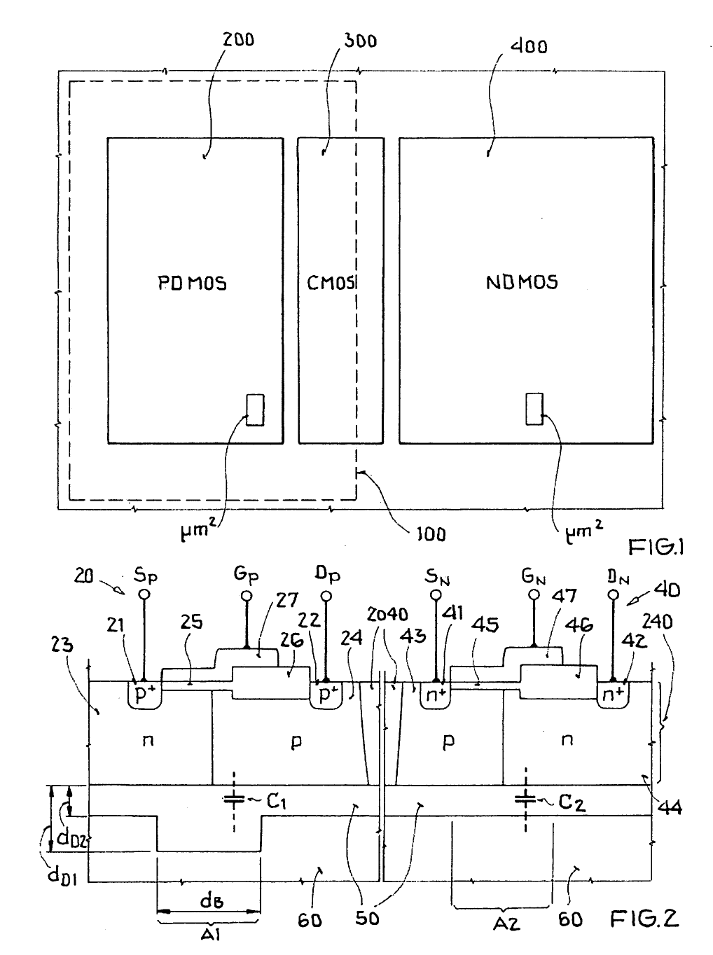

Several regions 200, 300, 400 of an integrated circuit are shown in a schematic plan view in FIG. 1. A plurality of PDMOS transistors are placed in a first region 200. A plurality of NDMOS transistors are placed in a second region 400. A third region 300 with analog and/or digital CMOS structures, which work together with the PDMOS transistors and/or the NDMOS transistors in the integrated circuit, is placed between said first region 200 and said second region 400. Integrated structures of this type, which have both power semiconductors (PDMOS/NDMOS) and low-power CMOS structures for evaluation and control, are also designated as smart power circuits.

Furthermore, a standardized unit area of 1 μm² in first region 200 and in second region 400 is shown schematically in FIG. 1. In the embodiment of FIG. 1, both the PDMOS transistors and the NDMOS transistors are isolated from a substrate (not shown in FIG. 1) by a dielectric (not shown in FIG. 1). To reduce a substrate capacitance of the PDMOS transistors in comparison with the substrate, the substrate is removed below the PDMOS transistors in a fourth region 100. In the exemplary embodiment of FIG. 1, fourth region 100 is thereby larger than first region 200 and encloses the first region 200 completely. Fourth region 100, moreover, is spatially distanced from second region 400 with the NDMOS transistors. In the embodiment of FIG. 1, all PDMOS transistors are locally placed together within first region 200. In the same way, all NDMOS transistors are placed in second region 400 and connected via metallization levels, not shown in FIG. 1, to first region 200 and/or third region 300.

FIG. 2 shows an integrated circuit, which has a component region 240 with an NDMOS transistor 40 and a PDMOS transistor 20. Further-more, the integrated circuit has a substrate 60, which is isolated from component region 240 by a buried dielectric 50. In a first region A₁ of the PDMOS transistor 20, dielectric 50 is formed with a greater first thickness d_{D1} compared with a second, smaller thickness d_{D2} of dielectric 50 in a second region A₂ of NDMOS transistor 40.

This structure advantageously produces a first lower capacitance C₁ between first region A₁ of PDMOS transistor 20 and substrate 60 in comparison with a second, higher capacitance C₂ between second region A₂ of NDMOS transistor 40 and substrate 60. Substrate 60 is preferably made of silicon. In the exemplary embodiment of FIG. 2, first region A₁ is a first transition region between a P-well 24 and an N-well 23 of PDMOS transistor 20. Second region A₂ is, for example, a second transition region between an N-well 44 and a P-well 43 of NDMOS transistor 40.

In the embodiment of FIG. 2, PDMOS transistor 20 and NDMOS transistor 40 are isolated from one another by a trench 2040 filled with an additional dielectric.

In the following, the structure of PDMOS transistor 20 and of NDMOS transistor 40 will be described briefly. The shown structure is sketched schematically as a preferred exemplary embodiment for a PDMOS transistor 20 and/or an NDMOS transistor 40.

PDMOS transistor 20 has a source terminal S_{P} (source), a gate terminal G_{P} (gate), and a drain terminal D_{P} (drain). The source terminal S_{P} is connected to a highly p-doped source semiconductor region 21. This source semiconductor region 21 is placed by implantation within an N-well 23 of PDMOS transistor 20. The drain terminal D_{P} is connected to a highly p-doped drain semiconductor region 22, which is placed by implantation in a P-well 24 of the PDMOS transistor 20. N-well 23 and P-well 24 are adjacent to one another below a gate oxide 25. The gate terminal G_{P} is connected to a gate electrode 27, which is made, for example, of polycrystalline silicon. Gate electrode 27 is thereby placed on gate oxide 25 and partially on a field oxide 26.

NDMOS transistor 40 has a source terminal S_{N} (source), a gate terminal G_{N} (gate), and a drain terminal D_{N} (drain). The source terminal S_{N} is connected to a highly n-doped source semiconductor region. This source semiconductor region 41 is placed by implantation within a P-well 43 of NDMOS transistor 40. The drain terminal D_{N} is connected to a highly n-doped drain semiconductor region 42, which is placed by implantation in an N-well 44 of NDMOS transistor 40. P-well 43 and N-well 44 are adjacent to one another below a gate oxide 45. The gate terminal G_{N} is connected to a gate electrode 47, which is made, for example, of polycrystalline silicon. Gate electrode 47 is thereby placed on gate oxide 45 and partially on a field oxide 46.

In region A₂ of NDMOS transistor 40, buried dielectric 50 together with substrate 60 functions as an additional gate electrode. The thickness d_{D2} of buried dielectric 50, for example, of a silicon dioxide, thereby influences the breakdown voltage of NDMOS transistor 40. NDMOS transistor 40 has a highest drain-side breakdown voltage at about 500 nm. The PDMOS transistor has its highest drain-side breakdown voltage, in contrast, at at least 1000 nm, preferably 2000 nm of the dielectric thickness d_{D1}. NDMOS transistor 40 thereby profits from the depletion charge in the drift zone, which is induced by the silicon substrate electrode 60 (RESURF effect). A too thick, buried dielectric 50 weakens this positive effect.

PDMOS transistor 20, in contrast, because of the different charge carrier polarity cannot profit from the RESURF effect. The majority of the depletion charge is induced here in N-well 23 and not in the drift zone, which forms in particular in P-well 24. The depletion charge induced by substrate electrode 60 in N-well 23, however, has a detrimental effect on the breakdown voltage of the drain of PDMOS transistor 20. This effect of the depletion charge in the first region A₁ is reduced by enlarging the thickness d_{D1} of buried dielectric 50 in first region A₁ in PDMOS transistor 20. To accomplish this, as shown in FIG. 2, the thickness d_{D1} of dielectric 50 is locally increased below the transition from n-doped N-well 23 to p-doped P-well 24. The thickness d_{D1} of dielectric 50 in said first region A₁ is preferably at least 1000 nm. The extension d_{B} of the first region A₁ is preferably at least 7 μm.

Different manufacturing options for different dielectric thicknesses are shown schematically in FIGS. 4 and 5. In FIG. 4, first, dielectric 500 is produced, for example, by oxidation or implantation of oxygen with a first thickness d_{D1}′ and with a second smaller thickness d_{D2}′ on substrate 600. Proceeding from seed windows 760 as the crystallization nucleus, an amorphous silicon layer is crystallized to single-crystal silicon 700 (c-Si), and thus dielectric region 500 between seed windows 760 is at least partially overgrown by single-crystal silicon 700.

FIG. 5 shows a different option. Here, again proceeding from a seed window 760′ acting as a crystallization nucleus, polycrystalline silicon 800 is recrystallized to single-crystal silicon 700′ by the local energy input of a laser beam 1000. The different thicknesses d_{D1}″, d_{D2}″ of dielectric 550 were previously formed on substrate 600′.

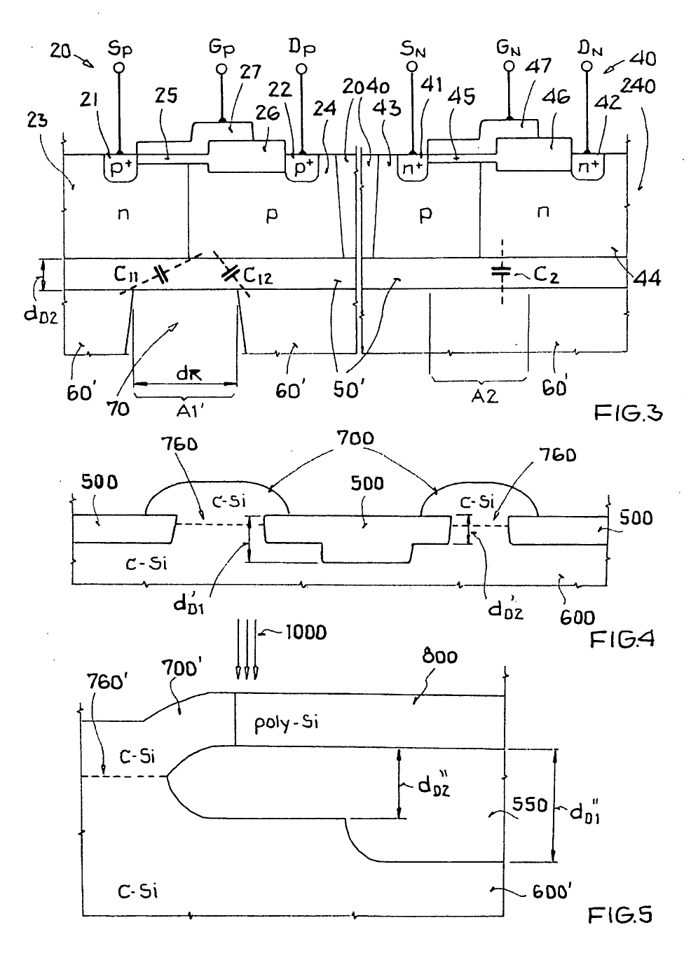

Alternatively to increasing the dielectric thickness, as shown in FIG. 3, the substrate may be removed below buried dielectric 50′ in a first region A₁′. FIG. 3 therefore shows an integrated circuit, which has a component region 240 with an NDMOS transistor 40 and a PDMOS transistor 20. Furthermore, the integrated circuit has a substrate 60′, which is isolated from component region 240 by a buried dielectric 50′. In a first region A₁ of PDMOS transistor 20, the substrate 60′ is removed in first region A₁′ of PDMOS transistor 20.

In the transition region between P-well 24 and N-well 23, substrate 60′ is preferably removed to a width d_{R}, which is advantageously wider than the thickness d_{D2} of dielectric 50′. Substrate 60′ may be removed, for example, by means of KOH etching. This leads to an extensive reduction of the negative effect of silicon substrate electrode 60′ on PDMOS transistor 20. Advantageously, before the KOH etching, substrate 60′ has been thinned to a thickness of 200 nm.

Substrate trench 70 arising due to the KOH etching in substrate 60′ may be left exposed, as shown in FIG. 3, or alternatively be filled with another dielectric. The remaining (parasitic) capacitances C₁₁ and C₁₂ to substrate 60′ remaining outside substrate trench 70 are thereby significantly lower than capacitance C₂. First region A₁′, in which substrate 60′ is removed may comprise larger dimensions, particularly the base area (200, see FIG. 1) of all PDMOS transistors (20), which is different from what is shown in FIG. 3.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An integrated circuit comprising:
a component region having at least one NDMOS transistor and at least one PDMOS transistor; and
a substrate that is isolated from the component region by a dielectric, the component region, dielectric, and substrate forming a first substrate capacitance standardized to a unit area in a first region of the PDMOS transistor and a second substrate capacitance standardized to the unit area in a second region of the NDMOS transistor,
wherein the first substrate capacitance standardized to the unit area is reduced in comparison with the second substrate capacitance standardized to the unit area.

2. The integrated circuit according to claim 1, wherein the first substrate capacitance standardized to the unit area is reduced in comparison with the second substrate capacitance standardized to the unit area by a greater first thickness of the dielectric in the first region of the PDMOS transistor in comparison with a second thickness of the dielectric in the second region of the NDMOS transistor.

3. The integrated circuit according to claim 2, wherein a width of the first region is greater than the first thickness of the dielectric in the first region.

4. The integrated circuit according to claim 1, wherein the first substrate capacitance standardized to the unit area is reduced in comparison with the second capacitance standardized to the unit area by removing the substrate in the first region of the PDMOS transistor.

5. The integrated circuit according to claim 1, wherein the first region is a transition region of an N-well and a P-well of the PDMOS transistor.

6. The integrated circuit according to claim 1, wherein a plurality of PDMOS transistors are formed in the first region and/or a plurality of NDMOS transistors are formed in the second region.

7. The integrated circuit according to claim 1, wherein the first region is spatially distanced from each NDMOS transistor.

8. A method for manufacturing an integrated circuit, the method comprising the steps of:
providing a substrate, a dielectric that is adjacent to the substrate, and a semiconductor region that is adjacent to the dielectric;
forming in the semiconductor region at least one NDMOS transistor;
forming in the semiconductor region at least one PDMOS transistor; and
forming the dielectric thicker in a first region of the PDMOS transistor than in a second region of the NDMOS transistor to produce the dielectric.

9. A method for manufacturing an integrated circuit, the method comprising the steps of:
providing a dielectric adjacent to a substrate and a semiconductor region, which is isolated from the substrate by the dielectric;
forming at least one NDMOS transistor in the semiconductor region;
forming at least one PDMOS transistor in the semiconductor region; and
removing the substrate in a first region that is below the PDMOS transistor.

10. The method according to claim 9, wherein the-substrate is removed by etching.
